(19) United States
(12) Patent Application Publication
(10) Pub. No.: US 2026/0219337 A1
(43) Pub. Date: Jul. 30, 2026

(54) QUANTUM MAGNETOMETER

(71) Applicants: SOCIÉTÉ DE COMMERCIALISATION DES PRODUITS DE LA RECHERCHE APPLIQUÉE SOCPRA SCIENCES ET GÉNIE S.E.C., Sherbrooke (CA); National Research Council of Canada, Ottawa (CA); The Royal Institute for the Advancement of Learning/McGill University, Montreal (CA); The Governors of the University of Alberta, Edmonton (CA); Quantum Silicon Inc., Edmonton (CA)

(72) Inventors: Michel Pioro-Ladrière, Sherbrooke (CA); Ryan Howard Foote, Sherbrooke (CA); Robert A. Wolkow, Edmonton (CA); Jason Pitters, Ottawa (CA); William Coish, Montreal (CA); Felix Fehse, Montreal (CA)

(73) Assignees: SOCIÉTÉ DE COMMERCIALISATION DES PRODUITS DE LA RECHERCHE APPLIQUÉE SOCPRA SCIENCES ET GÉNIE S.E.C., Sherbrooke, QC (CA); National Research Council of Canada, Ottawa, ON (CA); The Royal Institute for the Advancement of Learning/McGill University, Montreal, CA (CA); The Governors of the University of Alberta, Edmonton, AB (CA); Quantum Silicon Inc., Edmonton, AB (CA)

(21) Appl. No.: 19/142,334

(22) PCT Filed: Dec. 27, 2023
(86) PCT No.: PCT/CA2023/051766

§ 371 Date: Jun. 23, 2025

Related U.S. Application Data
(60) Provisional application No. 63/435,558, filed on Dec. 28, 2022.

(51) Int. Cl. G01R 33/06; G01R 33/00; G01R 33/09; G01R 33/12

(52) U.S. Cl. CPC G01R 33/066; G01R 33/0017; G01R 33/0029; G01R 33/098; G01R 33/1284

(57) ABSTRACT

A quantum magnetometer for measuring a magnetic field is provided. A Pauli Spin Blockade (PSB) system having, the at least discrete physical feature with a given spin state tunnel coupled to each of a source and a drain, is provided. The at least discrete physical feature is positioned between the source and the drain. A detector is configured to detect a magnetic field-dependent spin state at one or more of the source lead or the drain lead. An amplifier is configured to amplify the detected magnetic field-dependent transport current in some inventive embodiments.

### RELATED APPLICATIONS

This application claims priority benefit of U.S. Provisional Application Ser. No. 63/435,558 filed Dec. 28, 2022; the contents of which are hereby incorporated by reference.

### FIELD OF THE INVENTION

The present invention relates to magnetometry. More particularly, it relates to a highly sensitive and highly efficient quantum magnetometer capable of measuring magnetic phenomena at the quantum scale with minimal required current flow.

### BACKGROUND OF THE INVENTION

The detection of weak magnetic fields with high spatial resolution is a task of great importance in diverse areas, from fundamental physics and chemistry, to practical applications that include data storage and medical imaging. This task can be tackled by magnetic-field sensors, based on various operating principles. Low-temperature magnetometry has been successfully used to image a range of nontrivial magnetic phenomena, e.g., vortices in superconductors, exotic magnetic structures, and current-induced magnetic fields in various systems including topological insulators. The applicability of the different magnetic-field sensors (SQUIDs, Hall bars, NV centers, etc.) for specific tasks is determined by a number of characteristics, including magnetic-field sensitivity and detection volume, the latter one related to the achievable spatial resolution.

However, existing magnetometers are highly susceptible to noise and interference given the presence of current flow required for their operation. Furthermore, their range of utility can be limited by requisite operating conditions or control electronics (ultra-low temperatures, lasers or optical cavities, etc.). Accordingly, such existing magnetometers are incapable of detecting magnetic fields arising from quantum phenomena with a high degree of sensitivity and efficiency required for observing single particles such as a single electron.

The ability to observe single particles is of increasing importance given that hydrogen-terminated silicon (H: Si) surfaces are a promising platform for atomic circuitry. That is, hydrogen desorption, on the H: Si surface allows creation of dangling bond (DB) based circuits for next generation ultimately miniaturized low power nanoelectronic devices beyond complementary metal-oxide-semiconductor (CMOS) technology. The attractive properties of hydrogen-terminated silicon illustratively include inertness, thermal stability, low defect densities, and unique attributes of the silicon surface dangling bonds. Fundamental properties of isolated dangling bonds have been studied extensively. It has been shown that they are electronically isolated from the host substrate and can hold charge, thereby acting as atomistic quantum dots that are amenable to being precisely placed and erased. Various functional elements such as quantum-cellular-automaton cells, binary transmission wires, and binary computational gates can be made by arranging dangling bonds close to each other. Dangling bonds on the H: Si surface have been shown to be rewritable as well as stable at room temperature making them an excellent candidate for atom scale devices. However, further observation of single particles, dopant atoms, or dangling bonds are required in order to fully understand such structures and to optimize this promising cutting-edge technology.

Thus, there exists a need for a quantum magnetometer that does not require current flow for operation, thus enabling it to be highly sensitive and highly efficient and capable of measuring magnetic phenomena at the quantum scale to observe single particles such as a single electron.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A is a schematic drawing of a prior art hydrogen terminated silicon (H: Si) surface with an STM tip in close proximity thereto;

FIG. 1B is a schematic drawing of the prior art H: Si surface of FIG. 1A in which the STM tip has removed a hydrogen atom from the silicon surface, leaving a dangling bond thereon as an exemplary discrete physical feature;

FIG. 2A is a schematic diagram showing a prior art forward bias obstruction of electrical current by the spin of a single electric charge;

FIG. 2B is a schematic diagram showing prior art lifting of the obstruction due to reverse bias configuration;

FIG. 3 is a schematic diagram of a quantum magnetometer according to embodiments of the present invention in which two proximal dangling bonds are used as exemplary discrete physical features;

FIG. 4 is a schematic diagram of a quantum magnetometer according to embodiments of the present invention in which a chain of at least 3 proximal dangling bonds are present as exemplary discrete physical features;

FIG. 5 is a schematic diagram of a quantum magnetometer according to embodiments of the present invention in which a plurality of aligned arrays of repeated copies of two proximal dangling bonds all with the same orientation are present as exemplary discrete physical features;

FIG. 6 is a schematic diagram of a quantum magnetometer according to embodiments of the present invention in which a plurality of altering orthogonal arrays of repeated copies of two proximal dangling bonds are present as exemplary discrete physical features;

FIG. 7 is a schematic diagram of a quantum magnetometer according to embodiments of the present invention in which an aligned array of chains is present, where a chain is 3 or more proximal dangling bonds, where each chain can have the same or different lengths as exemplary discrete physical features;

FIG. 8 is a schematic diagram of a quantum magnetometer according to embodiments of the present invention in which an alternating orthogonal array of chains is present, where a chain is 3 or more proximal dangling bonds, where each chain can have the same or different length as exemplary discrete physical features;

FIG. 9 is a schematic diagram of the quantum magnetometer of FIG. 5 in which a unit cell of the quantum magnetometer is shown within a dotted line box;

FIG. 10 is a schematic diagram of a unit cell including two dangling bonds separated by a plurality of lattice sites or dimer rows, this unit cell being suitable for substitution with the unit cell of FIG. 9 as exemplary discrete physical features;

FIG. 11 is a schematic diagram of a unit cell including a chain of single dangling bonds separated by at least one lattice site or dimer row, this unit cell being suitable for substitution with the unit cell of FIG. 9 as exemplary discrete physical features;

FIG. 12 is a schematic diagram of a unit cell including an aligned array of two dangling bonds separated by at least one lattice site or dimer row, this unit cell being suitable for substitution with the unit cell of FIG. 9 as exemplary discrete physical features;

FIG. 13 is a schematic diagram of a unit cell including a plurality of altering orthogonal arrays of repeated copies of two proximal dangling bonds separated by at least one lattice site or dimer rows, this unit cell being suitable for substitution with the unit cell of FIG. 9 as exemplary discrete physical features;

FIG. 14 is a schematic diagram of a unit cell including an aligned array of variable length chains of single dangling bonds separated by at least one lattice site or dimer row, this unit cell being suitable for substitution with the unit cell of FIG. 9 as exemplary discrete physical features;

FIG. 15 is a schematic diagram of a unit cell including an alternating orthogonal array of variable length chains of single dangling bonds separated by at least one lattice site or dimer row, this unit cell being suitable for substitution with the unit cell of FIG. 9 as exemplary discrete physical features;

FIG. 16A is a schematic diagram of a cell unit including two proximal dangling bond clusters of at least two dangling bonds, this unit cell being suitable for substitution with the unit cell of FIG. 9 as exemplary discrete physical features;

FIG. 16B is a schematic diagram of the cell unit of FIG. 16A in which the two dangling bond clusters are each represented as a single red dot, this unit cell being suitable for substitution with the unit cell of FIG. 9 as exemplary discrete physical features;

FIG. 17 is a schematic diagram of a cell unit including at least one chain of at least two proximal dangling bond clusters, this unit cell being suitable for substitution with the unit cell of FIG. 9 as exemplary discrete physical features;

FIG. 18 is a schematic diagram of a cell unit including an aligned array of at least two proximal dangling bond clusters, this unit cell being suitable for substitution with the unit cell of FIG. 9 as exemplary discrete physical features;

FIG. 19 is a schematic diagram of a cell unit including an alternating orthogonal array of at least two proximal dangling bond clusters, this unit cell being suitable for substitution with the unit cell of FIG. 9 as exemplary discrete physical features;

FIG. 20 is a schematic diagram of a cell unit including an aligned array of at least two chains of proximal dangling bond clusters, this unit cell being suitable for substitution with the unit cell of FIG. 9 as exemplary discrete physical features;

FIG. 21 is a schematic diagram of a cell unit including an alternating orthogonal array of at least two chains of proximal dangling bond clusters, this unit cell being suitable for substitution with the unit cell of FIG. 9 as exemplary discrete physical features;

FIG. 22 is a schematic diagram of a cell unit including two dangling bond clusters separated by at least one lattice site or dimer row, this unit cell being suitable for substitution with the unit cell of FIG. 9 as exemplary discrete physical features;

FIG. 23 is a schematic diagram of a unit cell including a chain of dangling bond clusters separated by at least one lattice site or dimer row, this unit cell being suitable for substitution with the unit cell of FIG. 9 as exemplary discrete physical features;

FIG. 24 is a schematic diagram of a unit cell including an aligned array of two dangling bond clusters separated by at least one lattice site or dimer row, this unit cell being suitable for substitution with the unit cell of FIG. 9 as exemplary discrete physical features;

FIG. 25 is a schematic diagram of a unit cell including at least one alternating orthogonal array of two dangling bond clusters separated by at least one lattice site or dimer row, this unit cell being suitable for substitution with the unit cell of FIG. 9 as exemplary discrete physical features;

FIG. 26 is a schematic diagram of a unit cell including an aligned array of chains of dangling bond clusters separated by at least one lattice site or dimer row, this unit cell being suitable for substitution with the unit cell of FIG. 9 as exemplary discrete physical features;

FIG. 27 is a schematic diagram of a unit cell including an alternating orthogonal array of chains of dangling bond clusters separated by at least one lattice site or dimer row, this unit cell being suitable for substitution with the unit cell of FIG. 9 as exemplary discrete physical features;

FIG. 28A is a side view schematic diagram showing a dopant, which is any substitutional donor or acceptor atom, located in a substrate and electronically accessible by a nearby surface dangling bond;

FIG. 28B is a unit cell including a dangling bond above a dopant represented by a green dot, of FIG. 28A, this unit cell being suitable for substitution with the unit cell of FIG. 9;

FIG. 29A is a side view schematic diagram showing a dopant, which is any substitutional donor or acceptor atom, located in a substrate and electronically accessible by a nearby surface dangling bond cluster;

FIG. 29B, like FIG. 29A, is a side view schematic diagram showing a dopant located in a substrate and electronically accessible by a nearby surface dangling bond cluster, where the dangling bond cluster is represented as a red dot;

FIG. 29C is a unit cell including a dangling bond cluster above a dopant represented by an orange dot, of FIGS. 29A and 29B, this unit cell being suitable for substitution with the unit cell of FIG. 9;

FIG. 30 is a schematic diagram of a unit cell including an array of at least two single dangling bonds located above a dopant, this unit cell being suitable for substitution with the unit cell of FIG. 9 as exemplary discrete physical features; and

FIG. 31 is a schematic diagram of a unit cell including an array of at least two dangling bond clusters located above a dopant, this unit cell being suitable for substitution with the unit cell of FIG. 9 as exemplary discrete physical features.

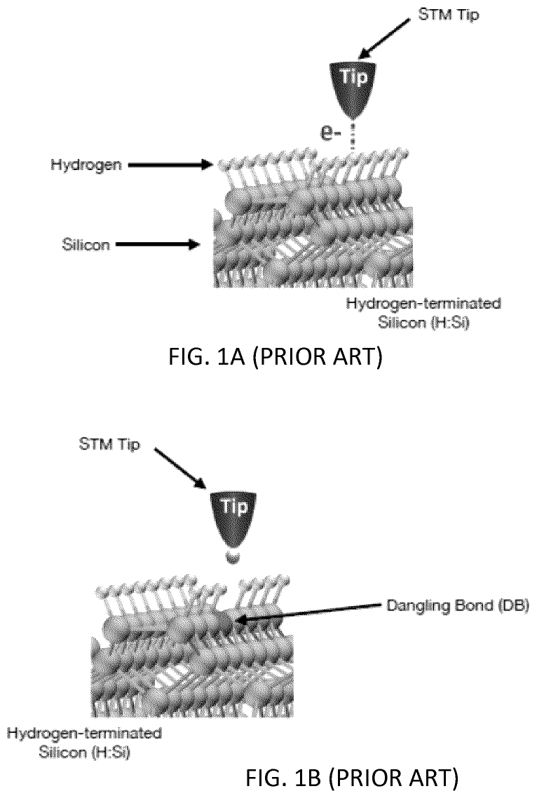

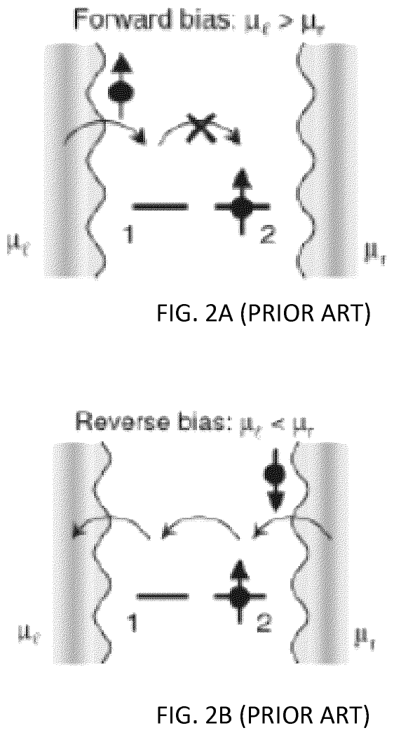

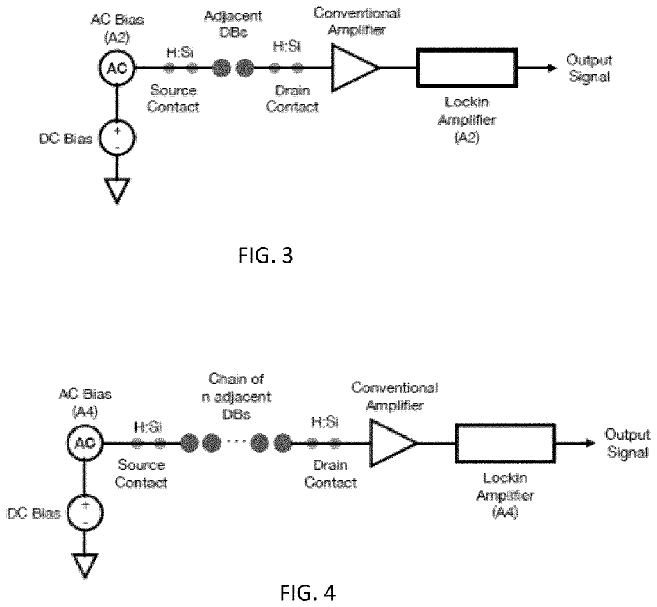

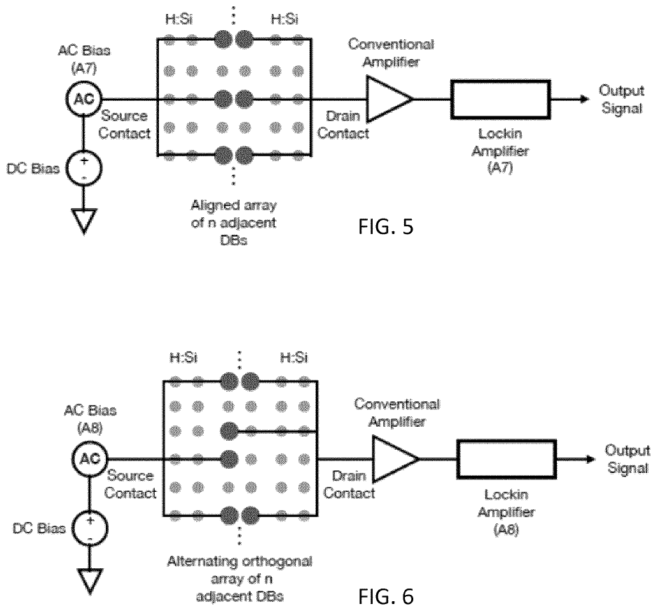

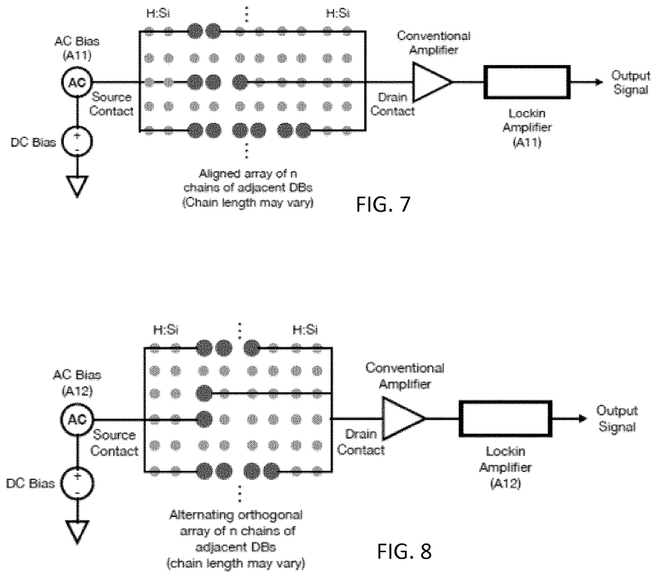

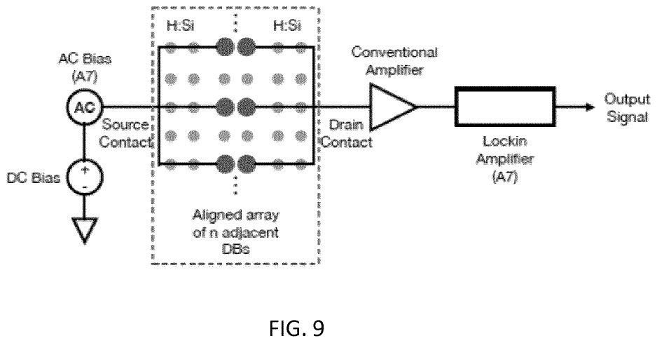

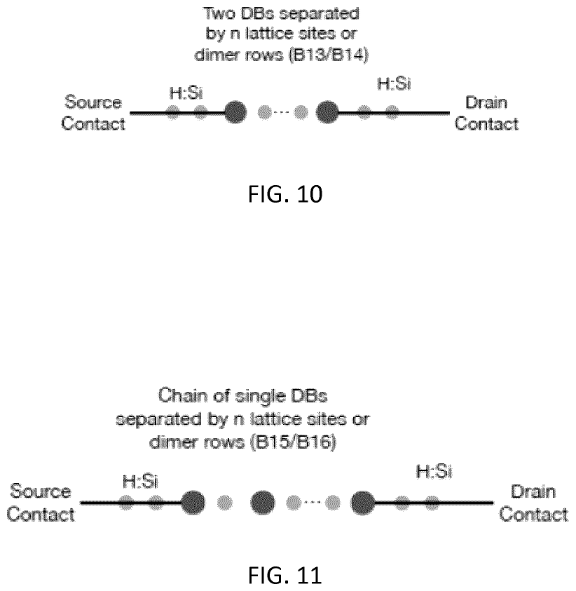

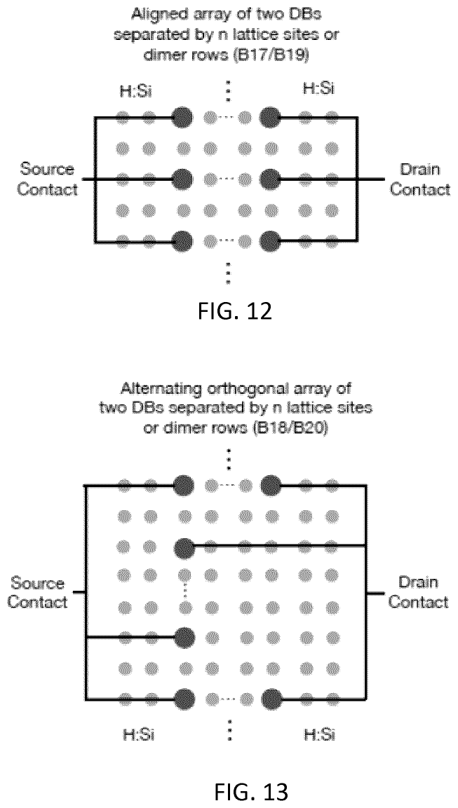

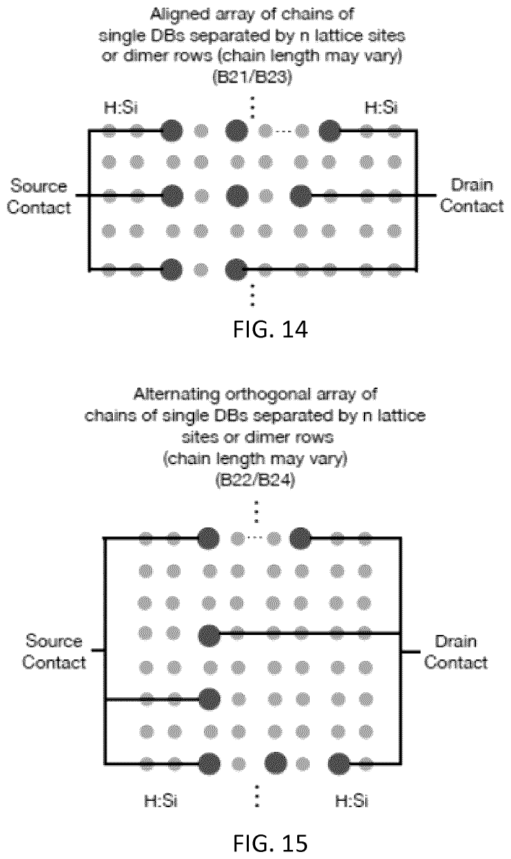

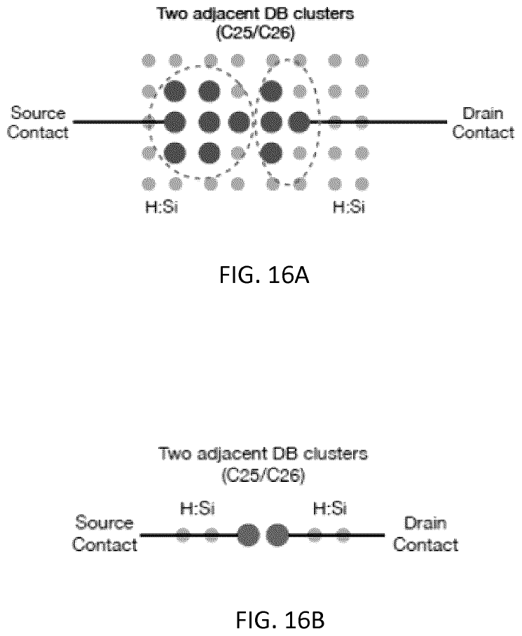

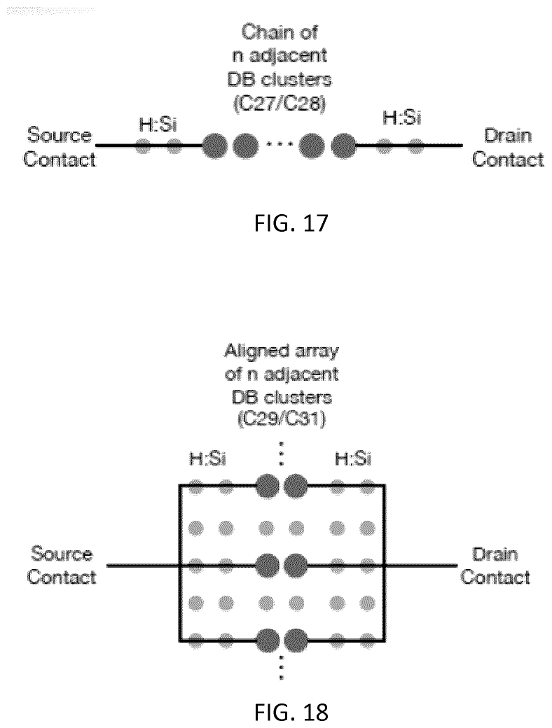

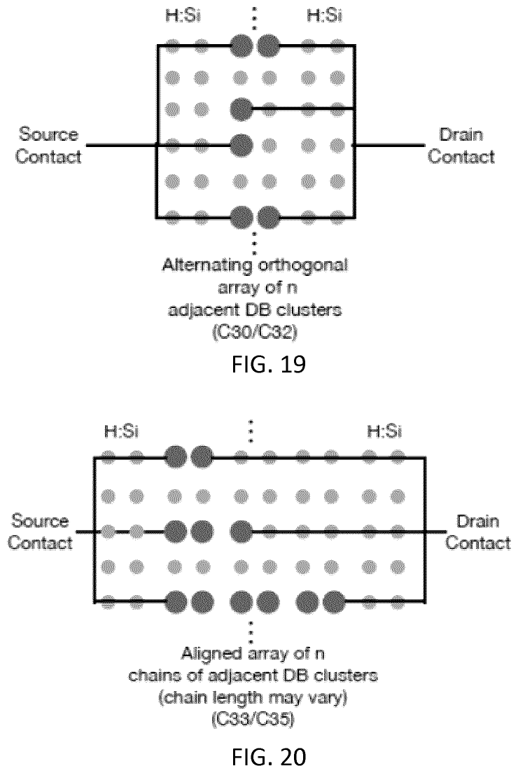

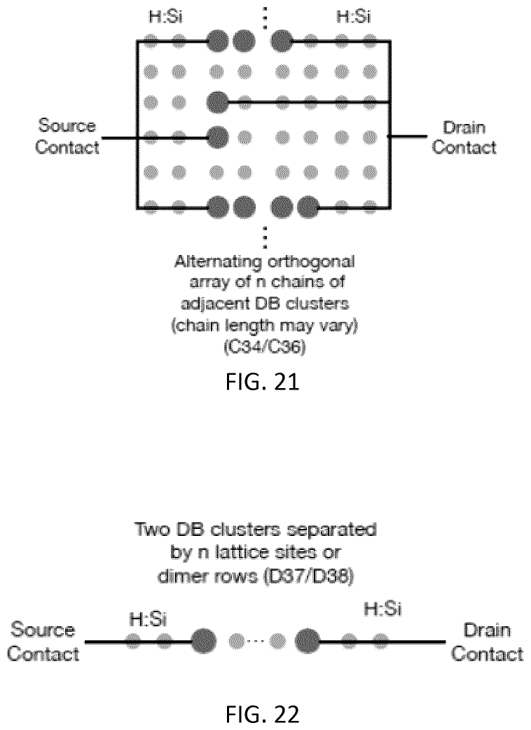

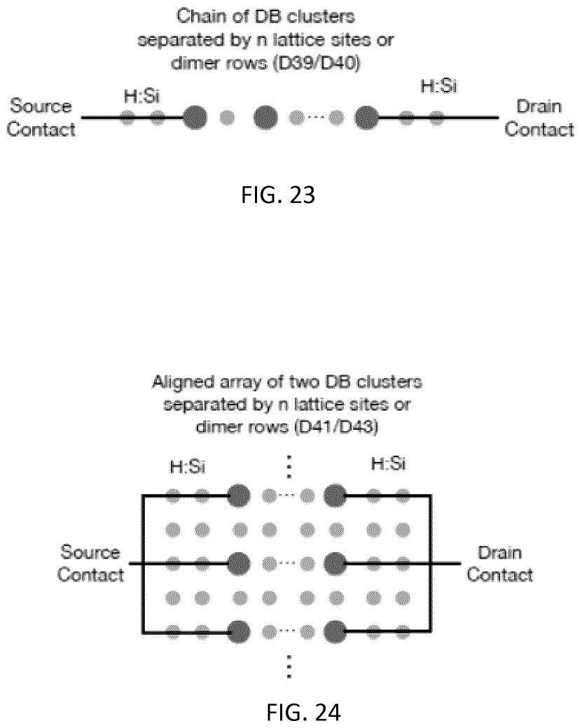

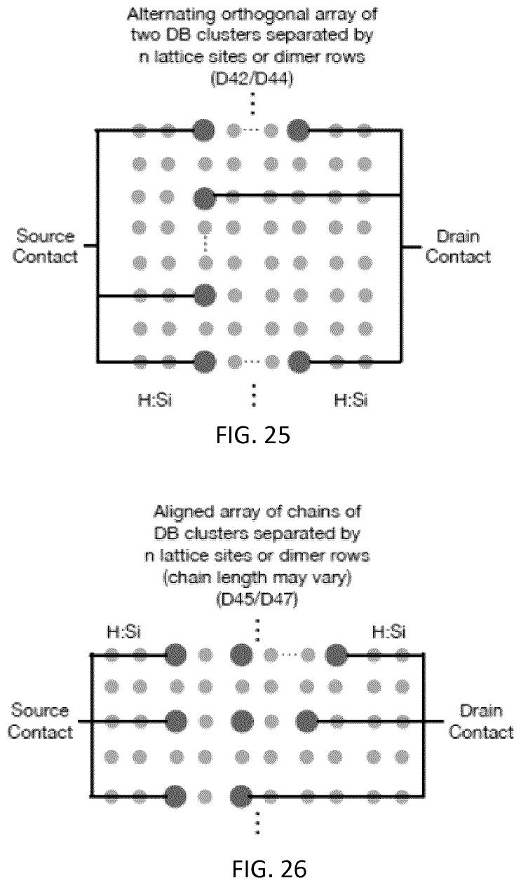

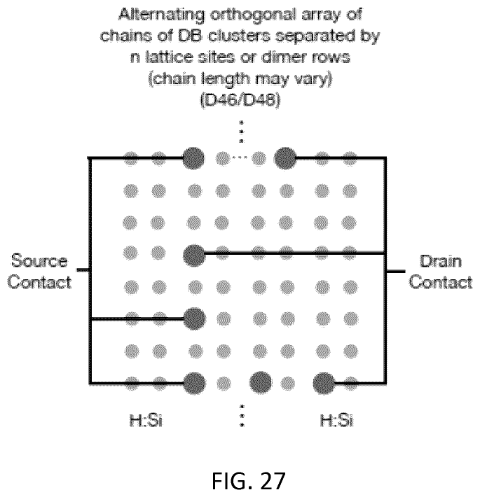

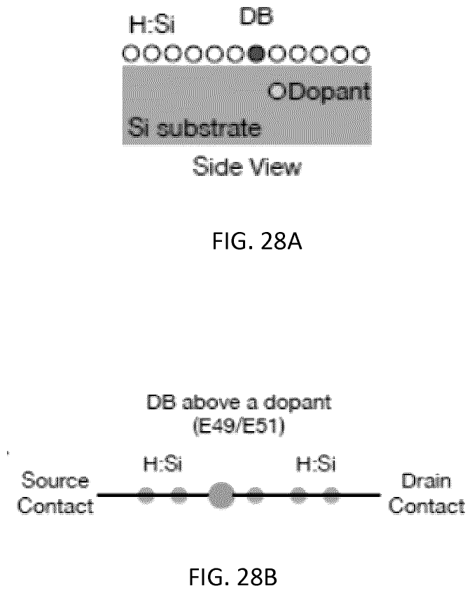

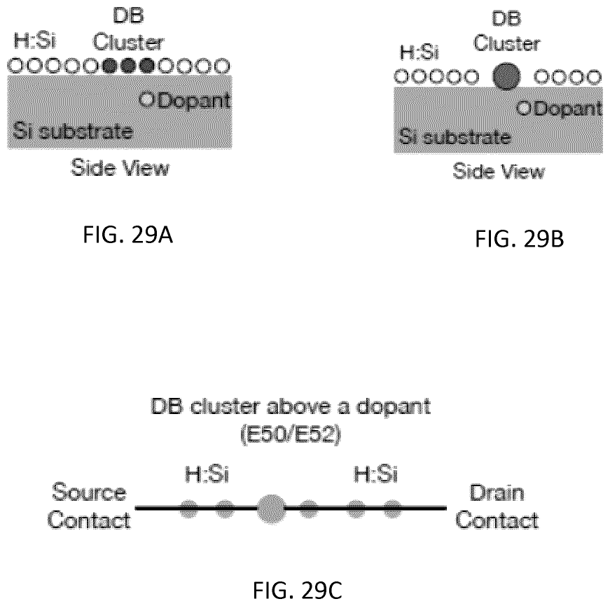

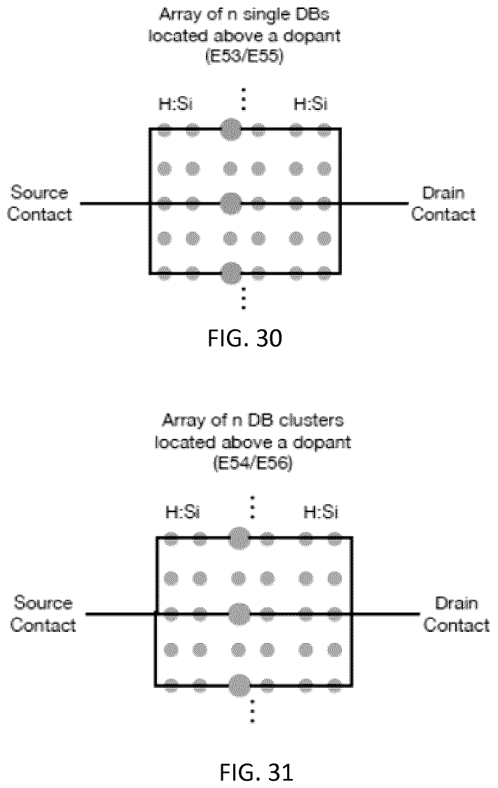

### DETAILED DESCRIPTION OF THE PREFERRED EMBODIMENTS

The present invention has utility as a quantum magnetometer that does not require current flow for operation, aside from detecting electronics. Thus, the present invention provides a highly sensitive and highly efficient quantum magnetometer capable of measuring magnetic phenomena at the quantum scale to observe single particles such as a single electron. It should also be appreciated that the present invention is also operative to measure macroscopic magnetic fields. As a result, an inventive magnetometer affords a wider detection range of magnetic fields than existing magnetometers.

Some embodiments of the inventive quantum magnetometer are configured to measure a magnetic field of at least one dangling bond. According to other inventive embodiments, the at least one dangling bond includes at least two single proximal dangling bonds or at least two dangling bond clusters. In still other inventive embodiments, the discrete physical feature from which a magnetic field is measured is a quantum dot or a dopant atom. While in several of the drawings, dangling bonds are shown as being separated by a single atom, it should be appreciated that the spacing therebetween can vary in a given array and need not have such a configuration. A dangling bond cluster is a grouping of two or more dangling bonds. According to embodiments, the at least two single proximal dangling bonds or at least two dangling bond clusters are positioned in an aligned array or in an altering orthogonal array. According to still other inventive embodiments, the proximal single dangling bonds or a plurality of proximal dangling bond clusters are provided as a chain. According to embodiments, multiple chains of proximal single dangling bonds or a plurality of proximal dangling bond clusters are positioned in an aligned array or in an alternating orthogonal array. According to still other inventive embodiments, the plurality of chains are provided with various lengths, in that the chains are not all equal in length. In still other inventive embodiments, the device is operated as a scanning probe. It should be understood that a dot as depicted in the figures can also independently, in each occurrence, represent either a quantum dot or a dopant atom.

The present invention will now be described with reference to the following embodiments. As is apparent by these descriptions, this invention can be embodied in different forms and should not be construed as limited to the embodiments set forth herein. Rather, these embodiments are provided so that this disclosure will be thorough and complete, and will fully convey the scope of the invention to those skilled in the art. For example, features illustrated with respect to one embodiment can be incorporated into other embodiments, and features illustrated with respect to a particular embodiment may be deleted from the embodiment. In addition, numerous variations and additions to the embodiments suggested herein will be apparent to those skilled in the art in light of the instant disclosure, which do not depart from the instant invention. Hence, the following specification is intended to illustrate some particular embodiments of the invention, and not to exhaustively specify all permutations, combinations, and variations thereof.

It is to be understood that in instances where a range of values are provided that the range is intended to encompass not only the end point values of the range but also intermediate values of the range as explicitly being included within the range and varying by the last significant figure of the range. By way of example, a recited range of from 1 to 4 is intended to include 1-2, 1-3, 2-4, 3-4, and 1-4.

Unless otherwise defined, all technical and scientific terms used herein have the same meaning as commonly understood by one of ordinary skill in the art to which this invention belongs. The terminology used in the description of the invention herein is for the purpose of describing particular embodiments only and is not intended to be limiting of the invention.

Unless indicated otherwise, explicitly or by context, the following terms are used herein as set forth below.

As used in the description of the invention and the appended claims, the singular forms “a,” “an” and “the” are intended to include the plural forms as well, unless the context clearly indicates otherwise.

Also as used herein, “and/or” refers to and encompasses any and all possible combinations of one or more of the associated listed items, as well as the lack of combinations when interpreted in the alternative (“or”).

As used herein, a “quantum dot” is defined as an order domain of from 1 to 1,200 atoms that exert quantum confinement on a charged species formed therein.

As used herein, a “dopant” is defined as a cluster of from 1 to 5 atoms of a substance that has electrical properties that are different than those of a surrounding semiconducting material. The dopant residing on a surface of, or within a matrix of the surrounding semiconducting material. By way of example, a phosphorus atom represents a dopant embedded a monolayer below a (100) silicon surface.

According to some inventive embodiments, a quantum magnetometer is provided that is based on a dangling bond operated in a Pauli-blockade regime. This has been theorized for a carbon nanotube quantum dot based magnetometer. G. Széchenyi et anon., Phys. Rev. B 95, 035431 (2017). In the Pauli-blockade regime, a large dc source-drain voltage is applied to serially coupled dangling bonds, and a dc current might flow via the transport cycle (0,1)→(1,1)→(0,2)→(0,1), where (N_{L}, N_{R}) denotes the number of electrons in the left and right dangling bonds. The (1,1)→(0,2) transition is blocked due to Pauli's exclusion principle if a (1,1) triplet state becomes occupied during the transport process, leading to a complete suppression of the current. The double dangling bond system is described by the two-electron Hamiltonian H=H_{B}+Hₜᵤₙ+H_{Δ}. The interaction of the external homogeneous magnetic field and the electron spins is determined according to Equation 1.

$${H}_{B} = \frac{1}{2} {μ}_{B} B \cdot ( {\hat{g}}_{L} {σ}_{L} + {\hat{g}}_{R} {σ}_{R} ) . \qquad Equation 1$$

Here, σ_{L/R} is the vector of Pauli matrices representing the spins of the electrons. The g tensors ĝ_{L} and ĝ_{R} are assumed to have the same principal values g⊥, g⊥, [symbol] , in the dangling bonds L and R. Furthermore, the principal axes of the g tensors enclose a small angle 2α<<1. The g tensors are given as ĝ_{D}= [symbol] t_{D}∘t_{D}+g⊥(1−t_{D}∘t_{D}), where t_{D}=(D sin α, 0, cos α) is the unit vector pointing along the local principal axis of g_{∥} in dangling bond D∈(L,R)≡(−1,1). Spin-conserving tunneling between the dangling bonds is represented by Hₜ=√2·t(|S_{g} [symbol] [symbol] S|+|S [symbol] [symbol] S_{g}|), where S [S_{g}] is the singlet state in the (1,1) [(0,2)] charge configuration. The last term H_{Δ}=−Δ|S_{g} [symbol] [symbol] S_{g}| describes the energy detuning between the (1,1) and (0,2) charge configurations. Finally, the incoherent tunneling processes from the source electrode to dangling bond L (from dangling bond R to the drain electrode) are characterized by the rate Γ_{L}(Γ_{R}).

In this model, the T₀ blockade appears in the case when the magnetic field is aligned with the x axis, B=(B,0,0). Then, taking the spin quantization axis along x, which coincides with the direction of B as well as with that of the average effective magnetic field ½ (ĝ_{L}+ĝ_{R})B, the (1,1) triplet state |T₀ [symbol] =\sqrt{½}(|↑↓ [symbol] +|↓↑ [symbol] ) is an energy eigenstate, implying that it is decoupled from the (0,2) charge configuration and therefore blocks the current. The other four two-electron energy eigenstates all contain a finite (0,2) component and therefore can decay to the single-electron states by emitting an electron to the drain; hence we call this special case the T₀ blockade. Note that the appearance of the T₀ blockade does not require the equality of the g-tensor principal values in the two dangling bonds.

Importantly, the T₀ blockade is maintained as long as the magnetic field lies in the xy plane. It is, however, lifted by a finite B_{z} component, as the latter couples T₀ to the singlet states. Therefore, in the vicinity of the T₀ blockade, the current is mostly determined by B_{z}. The decay rate of T̅₀, that is, the energy eigenstate that evolves from T₀ as B_{z} is turned on, is given by Γ̅=2Γ_{R}| [symbol] S_{g}|T̅₀ [symbol] |². T̅₀ is expressed using first-order perturbation theory in [symbol] B_{z}. After a leading-order expansion in the small angle α, and assuming g⊥<< [symbol] , fulfilled by the realistic parameter set used below, as shown in Equation 2.

$${\vert 〈 {S}_{g} \vert {\overline{T}}_{0} 〉}^{2} = {( \frac{{μ}_{B} g {B}_{z}}{\sqrt{2} t} \frac{g}{{g}_{-}} α )}^{2} . \qquad Equation 2$$

Note that this result is independent of the (1,1)-(0,2) energy detuning Δ.

Assuming that Γ̅ is the smallest tunnel rate in the transport process, current is expressed according to Equation 3.

$$I = 4 e \overline{Γ} = 8 e {{Γ}_{R} ( \frac{{μ}_{B} g {B}_{z}}{\sqrt{2} t} \frac{{g}_{\vert}}{{g}_{\vert}} α )}^{2} , \qquad Equation 3$$

and the Fano factor as F=7.

The dependence I(B_{z}) can be utilized for current-based magnetometry. Take an offset field with a small z component, B₀=(B₀ₓ, 0, B_{0z}). Consider the task that a small change δB_{z} in the z component of the field should be detected via measuring the current. The corresponding shot-noise-limited sensitivity for the device operated in the vicinity of the T₀ blockade can be expressed according to Equation 4.

$$S = \frac{\sqrt{7}}{4} \frac{tg}{a {μ}_{B} {g}^{2}} \frac{1}{\sqrt{{Γ}_{R}}} . \qquad Equation 4$$

For the parameter set [symbol] =30, g⊥=1, Γ_{R}=1 GHZ, t=5 μeV, α=3°, realistic for a clean carbon nanotube double quantum dot, Equation 4 implies a sensitivity of S≈37 nT/√Hz.

According to embodiments, the inventive quantum magnetometer is directionally sensitive, that is, variations of the current are caused by variations of the z component of the external magnetic field only. According to embodiments, the best sensitivities are achieved in the vicinity of the T₀ blockade region.

According to embodiments, the current is maximal around (B_{0z},B₀ₓ)=(±1 mT,80 mT). The reason for this is that singlet-triplet mixing is most efficient in these magnetic-field ranges. At these magnetic field ranges, the local effective magnetic fields ĝ_{L}B and ĝ_{R}B in the two dangling bonds differ significantly, and their energy scales |μ_{B}ĝ_{L}B| and |μ_{B}ĝ_{R}B| are comparable to the interdot tunnel amplitude t; these conditions ensure efficient singlet-triplet mixing and a large current. If the magnetic field is oriented along the same direction, but decreased in magnitude, |μ_{B}ĝ_{L,R}B|<<t, then the hybridized singlet states with energies around±√2·t are hardly mixed with the triplets around zero energy, hence the latter ones block transport and the current decreases.

According to embodiments, the sensitivity of such a device can reach a few tens of nT/√Hz. The sensitivity of a quantum Pauli-blockade magnetometer is not influenced directly by the temperature, see Equation 4. The only requirement on temperature for the quantum Pauli-blockade magnetometry scheme to work is that the orbital level spacing should dominate the thermal energy scale. It is of note that the dangling bonds of the present invention represent smaller controlled quantum structures relative to quantum dots and therefore provide larger orbital level spacings and allow for a higher temperature of operation and enhanced spatial resolution. For example, as a linear detector the sensitivity is around 50 nT/√Hz with a dynamical range of a few hundred microteslas when a working point of around (B_{0z},B₀ₓ)=(0.25,100) mT is chosen.

According to embodiments, the inventive quantum Pauli-blockade magnetometer is protected against electrical potential fluctuations: the overlap and hence the decay rate Γ̅=2Γ_{R}| [symbol] S_{g}|T̅₀ [symbol] |² of T̅₀ are independent of the (1,1)-(0,2) energy detuning Δ. Therefore, even if a weak noise induces fluctuations of Δ, the decay rate Γ̅ and hence the characteristics of current flow through the device remain unchanged, and the sensitivity of the magnetometer will not be degraded.

Notably, where the principal values [symbol] and g⊥ of the g tensors are identical in the two dangling bonds, the two key qualitative results are: (i) If the homogeneous magnetic field B₀ is oriented along x, then the T₀ blockade sets in, and the dependence of the current on the component of the magnetic field that is in the xz plane and perpendicular to B₀ allows the measurement of the latter; and (ii) The independence of the decay rate Γ̅ from the detuning Δ indicates that the magnetic-field sensitivity of the Pauli-blockade magnetometry is robust against electric potential fluctuations. Notably, these two results are not restricted to the case when g⊥ and [symbol] are identical in the two dangling bonds; if the g tensors are more generic, but still allow for the T₀ blockade to appear, then both properties (i) and (ii) remain. The generic condition for the T₀ blockade is that the local effective magnetic fields on the two dangling bonds should have the same absolute values: |ĝ_{L}B|=|ĝ_{R}B|. If such a magnetic-field orientation exists for the given g tensors, and the field is oriented along that direction, then a single (1,1) two-electron triplet state is decoupled from the others and blocks the current. If we take the spin quantization axis along ĝ_{L}B+ĝ_{L}B, then this blocking state is in fact T₀=\sqrt{½}(↑↓+↓↑).

According to embodiments, the inventive quantum Pauli-blockade magnetometer in some inventive embodiments is operative as a scanning probe while in other inventive embodiments, exquisitely sensitive magnetic field measurements are possible. For such use, an important requirement is the mechanical stability of the setup. This requirement is related to the fact that in the Pauli-blockade magnetometry setup, the measured quantity (current) is sensitive to a magnetic-field component that is perpendicular to the offset field. Recall that in the Pauli-blockade magnetometry, a homogeneous external magnetic field (offset field) is applied, which is almost aligned with the x axis of the reference frame; for example, B₀=(100,0,0.25) mT. Then, measuring the current provides a measurement of δB_{z}, that is, the z component of the unknown part of the magnetic field. However, in the presence of weak mechanical noise, influencing either the offset field direction or the dangling bond orientation, their enclosed angle will change. For example, consider the change when, due to some mechanical instability, the offset field suffers an unwanted rotation B₀→B′₀ around the y axis with a small angle δ= 1/50≈1 degree. This change will give rise to an offset-field z component B′_{0z}≈B₀ₓ sin β≈2 mT, far exceeding the original working-point value B_{0z}=0.25 mT. This observation highlights the requirement of a high degree of mechanical stability in potential future devices realizing the proposed magnetometry scheme.

According to embodiments, the inventive quantum magnetometer does not require electron movement and therefore there is no need for current flow in the inventive device, absent the detecting electronics used, and as a result, the inventive device is highly sensitive and highly efficient for measuring magnetic phenomena at the quantum scale to observe single particles such as a single electron or other discrete physical feature. In those inventive embodiments operating as a scanning probe, current flow is more likely to be invoked.

According to embodiments, an inventive quantum magnetometer is provided for measuring a magnetic field of at least one dangling bond, other discrete physical feature, or even a macroscopic magnetic field. According to other inventive embodiments, the quantum magnetometer includes a Pauli Spin Blockade (PSB) system having a source spin state and a drain spin state. According to magnetometer embodiments of the present invention, a dangling bond with a certain spin state is tunnel coupled to each of a source and a drain leads. It should be appreciated that the leads themselves are neither polarized nor have a particular spin state. As a result, dangling bond spins in the system enable a novel magnetometer and in which each electron that exits the source lead or enters the drain lead must have a spin state. The at least one dangling bond is configured to be positioned between the source spin state and the drain spin state. The PSB system is configured to apply a DC bias current across the at least one dangling bond when the at least one dangling bond or other discrete physical feature is positioned between the source spin state and the drain spin state of the PSB system. The quantum magnetometer additionally includes an offset magnetic field positioned between the source spin state and the drain spin state, a detector configured to detect a magnetic field-dependent transport current of the dangling bond, other discrete physical feature, or even a macroscopic magnetic field, or an amplifier configured to amplify the detected magnetic field-dependent transport current, or a combination thereof.

As noted above, some inventive embodiments of the inventive quantum magnetometer are configured to measure a magnetic field of at least one dangling bond or other discrete physical feature. In still other inventive embodiments, the at least one dangling bond includes at least two single proximal dangling bonds or at least two dangling bond clusters, a quantum dot, or a dopant. A dangling bond cluster is a grouping of two or more dangling bonds. According to still other inventive embodiments, the at least two single proximal dangling bonds or at least two dangling bond clusters are positioned in an aligned array or in an alternating orthogonal array. According to still other inventive embodiments, the proximal single dangling bonds or a plurality of proximal dangling bond clusters are provided as a chain. According to still other inventive embodiments, multiple chains of proximal single dangling bonds or a plurality of proximal dangling bond clusters are positioned in an aligned array or in an alternating orthogonal array. According to still other inventive embodiments, the plurality of chains are provided with various lengths, in that the chains are not all equal in length. In still other inventive embodiments, the device is operated as a scanning probe.

According to embodiments, the at least one dangling bond includes a plurality of single dangling bonds or a plurality of dangling bond clusters that are each separated by at least one lattice site or dimer row. According to embodiments, such plurality of single dangling bonds or a plurality of dangling bond clusters that are each separated by at least one lattice site or dimer row are positioned in an aligned array or in an alternating orthogonal array. According to other inventive embodiments, the plurality of single dangling bonds or dangling bond clusters that are each separated by at least one lattice site or dimer row form at least one chain. According to embodiments, the at least one chain includes a plurality of chains formed of single dangling bonds or dangling bond clusters that are each separated by at least one lattice site or dimer row. According to still other embodiments, such a plurality of chains are positioned in an aligned array or in an alternating orthogonal array. According to still other embodiments, the plurality of chains are provided with various lengths, in that the chains are not all equal in length. According to still other embodiments, the other discrete physical features are quantum dots, dopants, dangling bonds, or a combination thereof,

According to embodiments, the at least one dangling bond is positioned above a dopant hosted on a silicon substrate. According to embodiments, the at least one dangling bond is isolated from a bulk substrate. In still other embodiments, a quantum dot provides the function of the at least one dangling bond. According to embodiments, the quantum magnetometer is hosted in silicon or any other suitable semiconductor material.

According to embodiments, the DC bias current of the inventive quantum magnetometer is applied in parallel across at least two dangling bonds, dangling bond clusters, or chains. Applying the DC bias in parallel increases the signal to noise ratio or the magnetic field-dependent transport current. According to embodiments, the DC bias includes AC modulation.

According to embodiments, the inventive quantum magnetometer additionally includes a lock-in amplifier configured to measure the amplified magnetic field-dependent transport current. According to embodiments, the inventive quantum magnetometer additionally includes a static offset field, which according to embodiments is provided by a macroscopic permanent magnet, a fabricated micromagnet, a nearby magnetic atom, or a combination thereof. Such a static offset field provides customization and enhanced sensitivity of the quantum magnetometer. According to embodiments, the inventive quantum magnetometer additionally includes a global AC field. Such a global AC field is configured to lift the PSB system at a specific total magnetic field. According to embodiments, the inventive quantum magnetometer additionally includes an internal static offset field and/or an applied AC electron spin resonance (ESR) signal to monitor phase for sensitive detection of changes in the magnetic field. According to embodiments, such an internal static offset field is provided by any of a macroscopic permanent magnet, a fabricated micromagnet, a nearby magnetic atom, or a combination thereof. According to embodiments, the inventive quantum magnetometer additionally includes an integrated charge sensor configured to readout a magnetometer state versus the magnetic field. According to embodiments, the integrated charge sensor is a single electron transistor. According to embodiments, the inventive quantum magnetometer additionally includes RF-reflectometry configured to readout a magnetometer state versus the magnetic field.

According to embodiments, the inventive quantum magnetometer operates independent of temperature. According to embodiments, the inventive quantum magnetometer is configured to measure a magnetic field gradient. According to embodiments, the PSB system of the inventive quantum magnetometer is free of a source contact and a drain contact.

According to embodiments, the inventive quantum magnetometer additionally includes control circuitry, which may include logic gates constructed from dangling bonds. According to embodiments, the inventive quantum magnetometer additionally includes classical CMOS circuitry, which may include any combination of at least one amplifier and at least one voltage divider.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention but is not meant to be a limitation upon the practice thereof. The following claims, including all equivalents thereof, are intended to define the scope of the invention.

1. A quantum magnetometer for measuring a magnetic field, the quantum magnetometer comprising:
a Pauli Spin Blockade (PSB) system having, an at least discrete physical feature with a given spin state tunnel coupled to each of a source and a drain, the at least discrete physical feature positioned therebetween; and
a detector configured to detect a magnetic field-dependent spin state at one or more of said source lead or said drain lead,
an amplifier configured to amplify the detected magnetic field-dependent transport current, or a combination thereof measuring the magnetic field.

2. The quantum magnetometer of claim 1 wherein the at least one discrete physical feature is a dangling bond.

3. The quantum magnetometer of claim 1 wherein the at least one discrete physical feature is at least two proximal dangling bonds or at least two dangling bond clusters.

4. The quantum magnetometer of claim 3 wherein the two proximal dangling bonds or dangling bond clusters are positioned in an aligned array or in an alternating orthogonal array.

5. (canceled)

6. The quantum magnetometer of claim 1 wherein the at least one discrete physical feature is at least one quantum dot or at least one dopant.

7. (canceled)

8. The quantum magnetometer of claim 3 wherein the at least one dangling bond includes at least one chain of a plurality of proximal single dangling bonds or a plurality of proximal dangling bond clusters.

9. The quantum magnetometer of claim 8 wherein a plurality of chains are positioned in an aligned array or in an alternating orthogonal array.

10. (canceled)

11. The quantum magnetometer of claim 9 wherein the plurality of chains are not all equal in length.

12. The quantum magnetometer of claim 1 wherein the at least one discrete physical feature includes a plurality of single dangling bonds or a plurality of dangling bond clusters that are each separated by at least one lattice site or dimer row.

13. The quantum magnetometer of claim 12 wherein the plurality of single dangling bonds or dangling bond clusters that are each separated by at least one lattice site or dimer row are positioned in an aligned array or in an alternating orthogonal array or at least one chain.

14. (canceled)

15. (canceled)

16. (canceled)

17. The quantum magnetometer of claim 13 wherein the at least one chain is present as a plurality of chains positioned in an aligned array or an alternating orthogonal array.

18. (canceled)

19. The quantum magnetometer of claim 17 wherein the plurality of chains are not all equal in length.

20. The quantum magnetometer of claim 1 wherein the DC bias current is applied in parallel to increase a signal-to-noise ratio of the magnetic field-dependent transport current alone or in combination with AC modulation.

21. (canceled)

22. The quantum magnetometer of claim 1 further comprising a lock-in amplifier configured to measure the amplified magnetic field-dependent transport current.

23. The quantum magnetometer of claim 1 wherein the at least one discrete physical feature is positioned above a dopant hosted on a silicon substrate or is isolated from a bulk substrate.

24. (canceled)

25. (canceled)

26. The quantum magnetometer of claim 1 further comprising a static offset field or a global AC field.

27. (canceled)

28. The quantum magnetometer of claim 1 further comprising an internal static offset field and an applied AC electron spin resonance (ESR) signal to monitor phase for sensitive detection of changes in the magnetic field.

29. The quantum magnetometer of claim 1 further comprising an integrated charge sensor configured to readout a magnetometer state versus the magnetic field RF-reflectometry configured to readout a magnetometer state versus the magnetic field, or a combination thereof.

30. (canceled)

31. The quantum magnetometer of claim 1 wherein the PSB system is free of a source contact and a drain contact.

32. The quantum magnetometer of claim 1 further comprising control circuitry CMOS, circuitry, or a combination thereof.

33. (canceled)

34. (canceled)

35. (canceled)
